(19) United States
(12) Patent Application Publication
(10) Pub. No.: US 2006/0090851 A1
(43) Pub. Date: May 4, 2006

(54) Diffuser and method for using a diffuser in equipment for manufacturing semiconductor devices

(76) Inventors: Sung-Ho Kang, Gyeonggi-do (KR); Sung-Gil Kim, Gyeonggi-do (KR); Byung-Hyung Kim, Gyeonggi-do (KR); Young-dong Seo, Gyeonggi-do (KR); Sang-Cheol Ha, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/253,779

(22) Filed: Oct. 18, 2005

(30) Foreign Application Priority Data
Oct. 28, 2004 (KR) 2004-86552

(51) Int. Cl. H01L 21/306; C23F 1/00

(52) U.S. Cl. 156/345.33; 118/715; 118/723 E; 156/345.45; 156/912

(57) ABSTRACT

There is provided a diffuser for implementing a diffusing process in an equipment for manufacturing semiconductor devices to increase or maximize its productivity. The diffuser comprises a reaction pipe; a plate joined to the underside of the reaction pipe for sealing the reaction pipe and defining a work space therewithin. A plurality of wafers are disposed within the work space. A gas injection tube is provided for supplying a reactive gas to the work space. A plurality of plasma electrodes are disposed adjacent to the gas injection tube for applying high frequency power to a reactive gas to induce a plasma reaction. A protection member is adapted to cover a portion of the plasma electrodes inserted into the reaction tube located under the plurality of wafers, for preventing a substantial amount of polymer from being formed under the reactive tube due to a plasma reaction in the reactive gases

### CROSS-REFERENCE TO RELATED APPLICATION

This application claims the benefit of Korean Patent Application No. 10-2004-0086552, filed Oct. 28, 2004, the disclosure of which is hereby incorporated herein by reference in its entirety.

### BACKGROUND OF THE INVENTION

1. Technical Field

The present invention relates to equipment for manufacturing semiconductor devices, and, more particularly, to a diffuser and to a method for using a diffuser in equipment for manufacturing semiconductor devices.

2. Discussion of Related Art

In general, semiconductor devices are manufactured by selectively and repeatedly implementing several processes, such as photography, etching, diffusion, chemical vapor phase deposition, ion implantation, metal deposition, or the like, on a wafer.

Among the above processes, diffusion is implemented to introduce desired conductive impurities into the wafer under a high temperature atmosphere.

Diffusion is utilized to thermally diffuse the conductive impurities, such as phosphorous, in single crystal silicon or poly silicon, to heat the wafer under an oxygen atmosphere to obtain a thermal oxide film, or to implement annealing or baking.

Properties of the oxide film (for example, thickness) are sensitive to internal pressure of the diffusing apparatus which is determined by the gas flow of the conductive impurities supplied into the interior of the diffusion apparatus, the sealed condition of the interior, the discharge of remaining gas containing air, or the like.

However, when reactive gas which is heated by a heater or plasma reaction during the diffusion process flows under a plurality of wafers, the reactive gas is deposited on an inner wall or a plasma electrode under a relatively low temperature atmosphere to generate a polymer in powder form. The polymer is stripped in a mass from the wall or electrode by cleaning gas in an in-situ process, and is dropped onto a flange or plate placed at a lower end of the wafer. This mass of the polymer become particles which are scattered in the dispersion process to pollute the wafer.

A diffuser for use in the equipment for manufacturing the semiconductor devices will now be described with reference to the accompanying drawings.

FIG. 1 is a cross-sectional view of a conventional diffuser for use in equipment for manufacturing semiconductor devices, and FIG. 2 is a perspective view illustrating the interior of a reaction pipe provided with a gas injection pipe 18 and a plasma electrode 22 shown in FIG. 1.

Referring to FIGS. 1 and 2, the conventional diffuser for use in the equipment for manufacturing semiconductor devices includes (a) a bell-shaped reaction pipe 10, (b) a plate 12 placed under the reaction pipe 10 and moved up to seal the reaction pipe 10, (c) a boat 14 placed in a center of the plate 12 for inserting a plurality of wafers 26 and a plurality of heater blocks 24 into the reaction pipe 10, (d) a heater 16 arranged around an outer periphery of the reaction pipe 10 corresponding to the plurality of wafers 26 inserted into the boat 14, for increasing the temperature of the interior of the reaction pipe 10, (e) a gas injection pipe 18 inserted into the reaction pipe 10 adjacent to the plate 12, for injecting reactive gas onto the wafer 26 positioned in an upper portion of the reaction pipe 10, (f) a gas exhaust pipe 20, placed opposite to the gas injection tube 18 in the reaction tube 10, for exhausting the reactive gas injected onto the wafer 26 through the gas injection tube 18, and (g) a plurality of plasma electrodes 22 installed in parallel adjacent to the gas injection tube 18 in a similar manner as the gas injection tube and applying high frequency power to the reactive gas supplied from the gas injection tube 18 to induce a plasma reaction.

The plate 12 supports the boat 14 provided with the plurality of wafers 26 and the plurality of heater blocks 24, and is moved up and down by a lifter which is not shown to simplify the drawings. The heater blocks 24 obstruct the heat applied from the heater 14.

The gas injection tube 18, the plasma electrode 22, and the gas exhaust tube 20 are inserted from the exterior into a side wall of the reaction tube 10 adjacent to an edge of the plate 12.

The gas injection tube 18 inserted into the reaction tube 10 is formed with a plurality of holes (not shown) at regular intervals for injecting the reactive gas towards the wafer 26. The plasma electrode 22 is made of a conductive metal, but is covered by a tube of insulating material to prevent it from being damaged by reactive gas.

The conventional diffuser induces reaction in the reactive gas injected from the gas injection tube 18 to diffuse it onto the silicon wafer 26 with predetermined ion implanting energy.

However, the convention diffuser has the following disadvantages. First, in the reaction tube 10, the pressure and temperature in the position corresponding to the gas exhaust tube 20 under the heater block 24 is lower than the position corresponding to the wafer 26. The reactive gases are applied onto the tube by the electrostatic force of the plasma electrode 22, so that a significant amount of polymer, which indicated by reference numeral 30 in FIG. 3, is generated on the tube 10 enclosing the plasma electrode 22. As a result, a cleaning process has to be frequently conducted to eliminate the polymer 30, thereby decreasing overall productivity.

Second, in the course of implementing the in-situ cleaning process of supplying the reactive gas into the reaction tube 10 and inducing the plasma reaction to eliminate the polymer, the polymer 30 generated on the plasma electrode 22 is dropped on the plate 12, as shown in FIG. 3. Additional wet cleaning process has to be implemented to eliminate the polymer 30 dropped on the plate 12, thereby decreasing the overall productivity as well.

### SUMMARY

Therefore, the present invention is directed to provide a diffuser for implementing a diffusing process in an equipment for manufacturing semiconductor devices, which can restrain a polymer from being generated on a heater block or a tube enclosing a plasma electrode under the heater block and decrease a frequency of a cleaning process to eliminate the polymer, thereby increasing or maximizing its productivity.

Another object of the present invention is to provide a diffuser for implementing a diffusing process in an equipment for manufacturing semiconductor devices, which can prevent a polymer, which is generated on a tube enclosing a plasma electrode, from being dropped in an in-situ cleaning process and prevent a further implementation of a wet cleaning process, thereby increasing or maximizing its productivity.

A diffuser can comprise a reaction pipe. The reaction pipe is preferably bell-shaped. A plate is located under the reaction pipe for sealing the reaction pipe and defining a work space therewithin. The work space is arranged and structured to contain a plurality of wafers therein. A gas injection tube is provided for supplying a reactive gas to the work space. A plurality of plasma electrodes are disposed adjacent to the gas injection tube for applying high frequency power to a reactive gas to induce a plasma reaction. A protection member is adapted to cover a portion of the plasma electrodes inserted into the reaction tube located under the plurality of wafers for preventing a substantial amount of polymer from being formed under the reactive tube due to a plasma reaction in the reactive gas. The diffuser can also include a boat located in work space for inserting a plurality of wafers and a plurality of heater blocks into the reaction pipe, a heater for increasing temperature in the work space, a gas injection pipe located within the reaction for injecting reactive gas onto the wafers, a gas exhaust pipe for exhausting the reactive gas injected onto the wafer;, a plurality of plasma electrodes located adjacent to the gas injection tube for applying high frequency power to the reactive gas supplied from the gas injection tube to induce a plasma reaction, and a protection member for preventing a substantial amount of polymer from being formed on the plate.

The gas injection tube preferably injects phosphorous. The plasma electrode applies about 50 to 800 W RF power to induce the plasma reaction in the reactive gas. The NF₃ is the preferred cleaning gas which is injected via the gas injection tube.

The protection member preferably has an area more than an interval between the plurality of plasma electrodes. The protection member also can also enclose the plurality of plasma electrodes. The protection member can preferably be made of quartz. The diffuser according to claim 1, wherein the protection member is adapted to form a vacuum therein or be filled with inert gas therein. Preferably, the inert gas is nitrogen or argon, and more preferably, the protection member is filled with the inert gas, and/or the protection member is sealed and/or the protection member is filled with the inert gas which is circulated at a predetermined pressure.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a cross-sectional view of a conventional diffuser for use in equipment for manufacturing semiconductor devices;

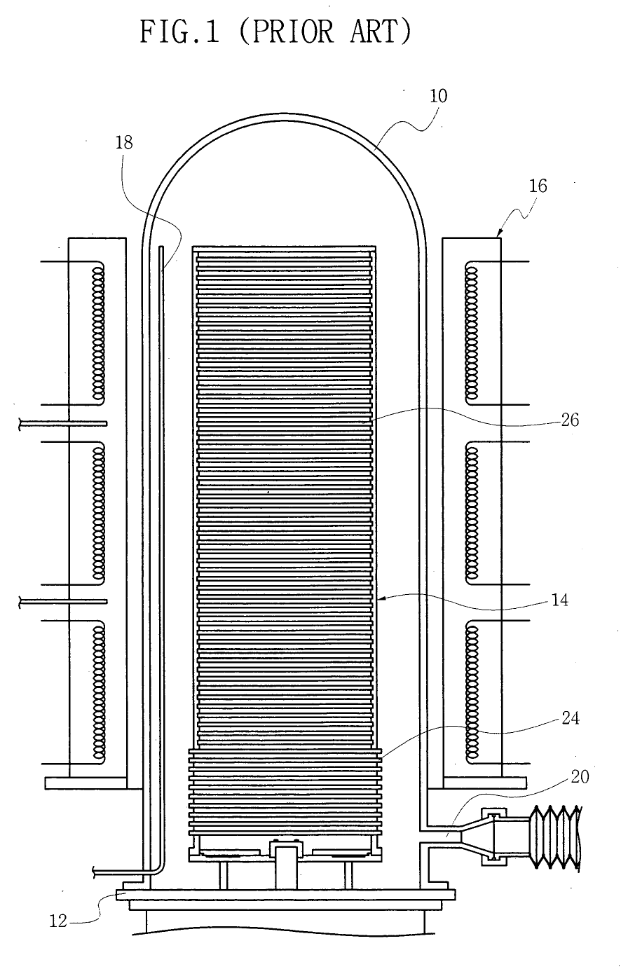

FIG. 2 is a perspective view illustrating an interior of a reaction pipe provided with a gas injection pipe and a plasma electrode shown in FIG. 1;

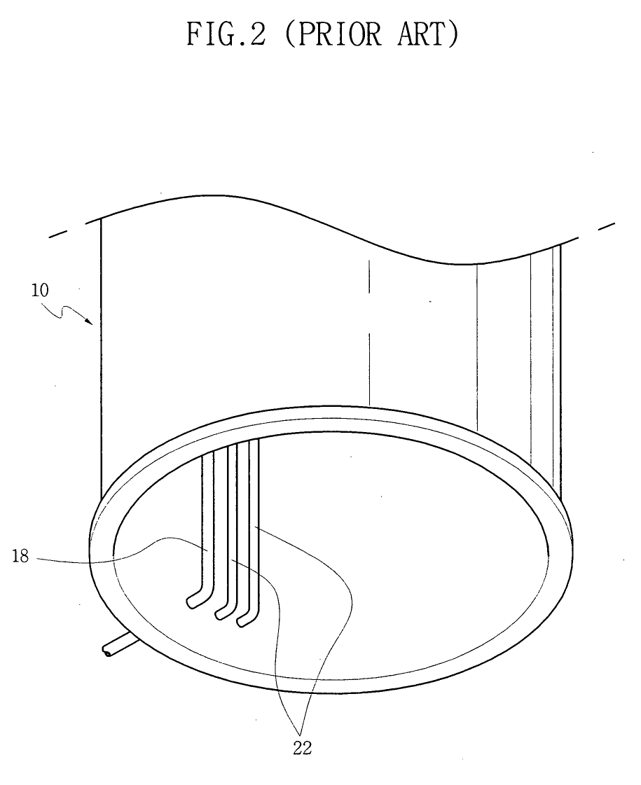

FIG. 3 is a view illustrating a polymer generated in an in-situ cleaning process in a conventional diffuser for use in equipment for manufacturing semiconductor devices;

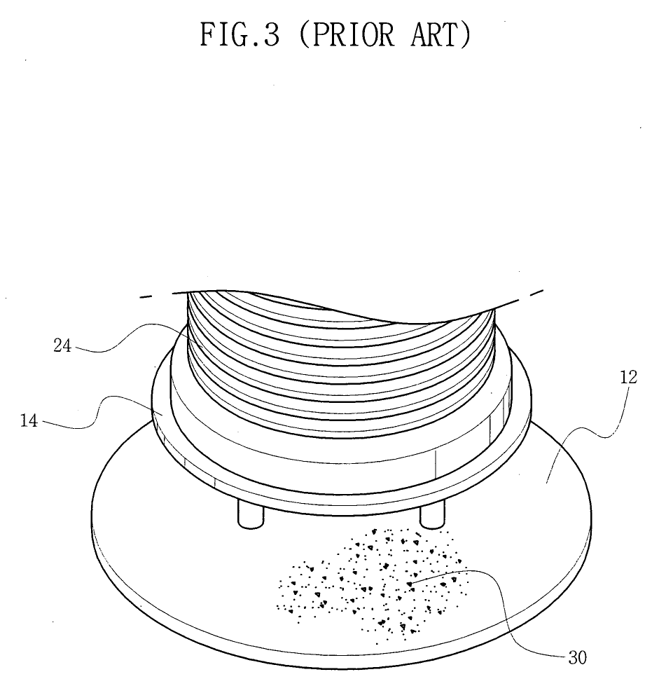

FIG. 4 is a cross-sectional view illustrating a diffuser furnace for use in equipment for manufacturing semiconductor devices according to an embodiment of the present invention;

FIG. 5 is a perspective view illustrating an interior of a reaction pipe provided with a gas injection pipe, a plasma electrode, and a protection member, shown in FIG. 4; and

FIG. 6 is a perspective view schematically illustrating a diffuser furnace for use in equipment for manufacturing semiconductor devices according to an embodiment of the present invention.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided as examples of the invention. Like numbers refer to like elements.

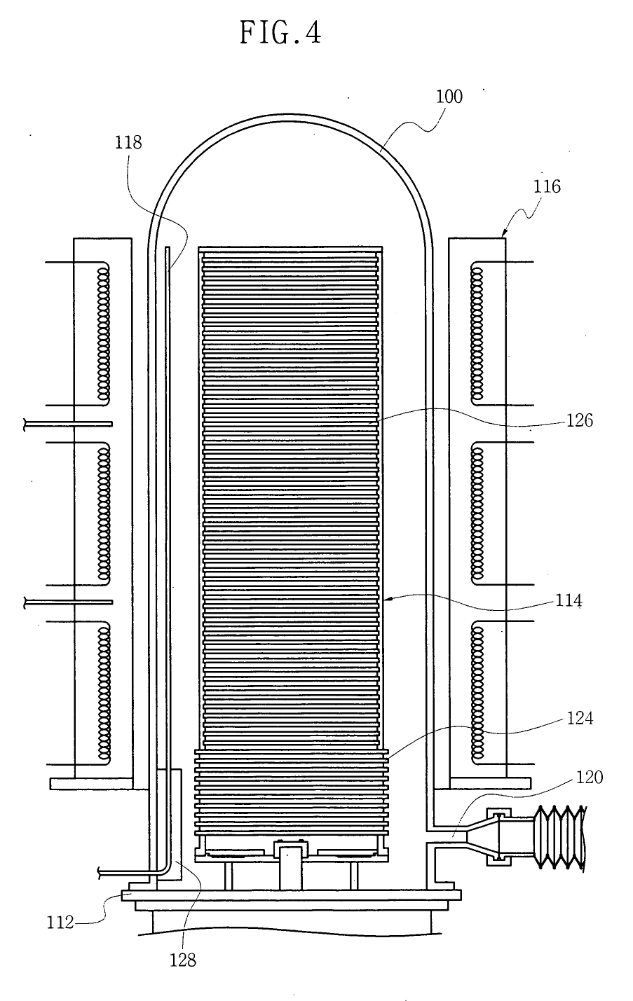

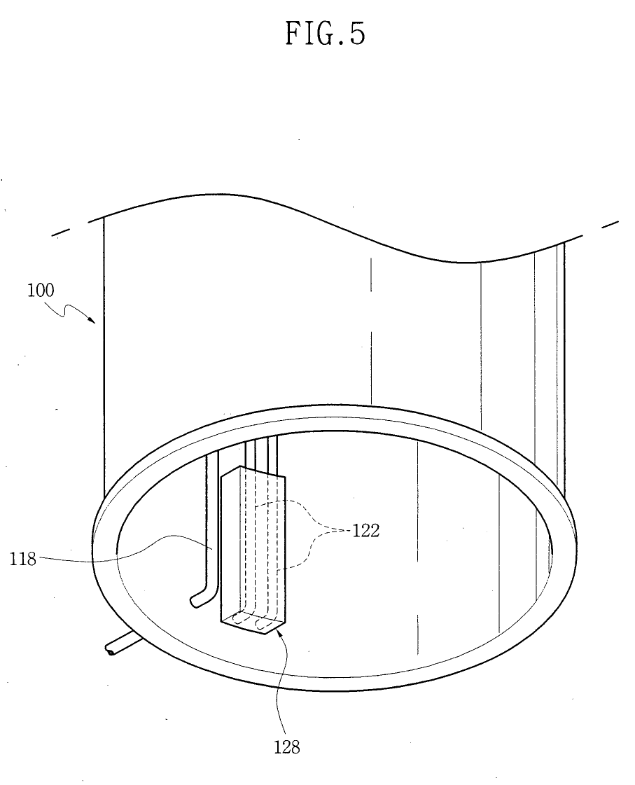

FIG. 4 is a cross-sectional view illustrating a diffuser furnace which can be used in the equipment for manufacturing semiconductor devices according to an embodiment of the present invention, and FIG. 5 is a perspective view illustrating the interior of a reaction pipe provided with a gas injection pipe 118, a plasma electrode 122, and a protection member 128, shown in FIG. 4.

Referring to FIGS. 4 and 5, the diffuser for use in the equipment for manufacturing semiconductor devices according to an embodiment of the present invention includes a bell-shaped reaction pipe 100 for providing a sealed space, a plate 112 placed under the reaction pipe 100 and moved up to seal the reaction pipe 100, a boat 114 placed on the plate 112 for inserting plurality of wafers 126 and plurality of heater blocks 124 into the reaction pipe 100, a heater 116, arranged around an outer periphery of the reaction pipe 100 corresponding to the plurality of wafers 126 inserted into the boat 114, for increasing temperature of the interior of the reaction pipe 110, a gas injection pipe 118 inserted into the reaction pipe 110 adjacent to the plate 112 for injecting reactive gases onto the wafer 126 positioned in an upper portion of the reaction pipe 100, a gas exhaust pipe 120, placed opposite to the gas injection tube 118 in the reaction tube 110, for exhausting the reactive gases injected onto the wafer 126 through the gas injection tube 118, and a plurality of plasma electrodes 122, installed in parallel adjacent to the gas injection tube 118 in a similar manner as the gas injection tube, for applying high frequency power to the reactive gases supplied from the gas injection tube 118 to induce a plasma reaction. A protection member 128, formed from a portion of the plasma electrode 122, is inserted into the reaction tube 100 to a position corresponding to the heater block 124 under the reaction tube 100, for preventing a polymer from being generated due to temperature difference between the reactive gases.

The gas injection tube 118 is formed with a plurality of holes at regular intervals for injecting the reactive gases in a direction parallel with the wafer 126 at the position corresponding to the wafer 126 inserted into the boat 114. The reactive gases injected from the holes of the gas injection tube are uniformly distributed over substantially the entire surface of the wafers 126 inserted into the boat 114, and flow to a lower portion of the reaction tube 100 to exhaust through the gas exhaust tube 120. For example, if the reactive gas is phosphorus, the gas is injected in a flow rate of about 2.5 liters/min through the gas injection tube 118.

The plasma electrodes 122 induce the plasma reaction in the reactive gas injected from the gas injection tube 118 to diffuse it onto the silicon wafer 126 with predetermined ion implanting energy at the position adjacent to the gas injection tube 118. Since the plasma electrode 122 is made of a conductive metal, a tube (not shown) for protecting the entire surface of the plasma electrode 122 inserted into the reaction tube 100 is integrally formed from a side wall of the reaction tube 100 to an upper portion of the boat 114 receiving the wafer 126.

For example, a plurality of plasma electrodes 122 can be applied from about 50 to 800 W RF power of about 3.56 MHz radio frequency to induce the plasma reaction in the reactive gas injected from the gas injection tube 118. At this time, when the RF power is applied to the reactive gas flowing to the lower portion of the reaction tube 100, the plasma state of reactive gas may be applied onto the tube enclosing the plasma electrode 122 due to the electrostatic force. In addition, the wafer 126 is heated on the upper portion of the reaction tube 100 by the heater 116, but the reactive gas may be cooled by the heater block 124, which directly blocks the heat generated from the heater 116, under the reaction tube 100. Consequently, the condensation of the reactive gas may cause the generation of the polymer to accelerate.

The protection member 128 is provided from the portion of the plasma electrode 122 inserted into the reaction tube 100 to the heater block 124 under the lowermost portion of the plurality of wafers 126 which is inserted into the boat 114, so as to prevent the plasma condensation of the reactive gas due to the RF power applied to the plasma electrode 122 and to prevent the polymer from being generated on the tube enclosing the plasma electrode 122 due to the electrostatic force of the reactive gases flowing under the reaction tube 10. Specifically, the protection member 128 has an area more than an interval between the plurality of plasma electrodes 122 and a height, preferably of from about 13 centimeters to about 20 centimeters, from the portion inserted into the reaction tube 100 to the heat block. Also, the protection tube is made of quartz having a constant thickness, preferably from about 3 centimeters to about 5 centimeters, in correspondence to a diameter of the tube enclosing the plasma electrode 122 inserted into the reaction tube 100.

The protection member 128 may be adapted to include a vacuum therein or to be filled with inert gas therein. Specifically, the protection member 128 may cover the space formed along a constant distance in the tube enclosing the plasma electrodes 122 thereunder, thereby forming a vacuum which is not affected by the RF power applied to the plasma electrode 122.

If the RF power of above a given level is applied, discharge may occur in the vacuum state since vacuum permeability is lower relative to the permeability of the inert gas such as nitrogen. The protection member 128 may be enclosed so that the space between the tubes enclosing the plasma electrodes 122 may be filled with the inert gas, such as nitrogen or argon.

Also, the protection member 128 may be supplied with an additional inert gas from the exterior of the reaction tube 100, so that the inert gas circulates from the interior of the protection member 128 to the reaction tube 100. At this time, if the RF power is applied to the plasma electrode 122 in the protection member in which the inert gas is filled or circulated, only the plasma reaction occurs in the protection member 128, and thus, plasma is not generated on the tube enclosing the plasma electrode 122 in the protection member 128 by the plasma reaction. In addition, since the plasma reaction does not occur in the reaction tube 100 outside the protection member 128, polymer is not generated by the electrostatic force of the reactive gas.

If the reactive gas charged to form positive ions by the plasma electrode 122 on the upper portion of the reaction tube 100 in which the wafer 126 is inserted flows in the lower portion of the reaction tube 100, the reactive gas is pushed towards the gas exhaust tube 120 with a force against the inert reactive gas charged to form positive ions in the protection member 128. Consequently, it is possible to prevent the polymer from being generated on the outer wall of the protection member 128 due to the reactive gas. Also, if the protection member 128 is heated to a desired temperature by the plasma reaction in the protection gas 128, it is possible to prevent the reactive gas from being cohered or condensed.

With the diffuser for use in the equipment for manufacturing the semiconductor devices according to an embodiment of the present invention, the protection member 128 is provided from the portion of the plasma electrode 122 inserted into the reaction tube 100 to the heater block 124 under the wafers 126 inserted into the boat 114, so as to prevent the polymer from being generated on the tube 100 enclosing the plasma electrode 122 due to the electrostatic force of the reactive gas flowing under the reaction tube 10 of the condensation of the reactive force. Hence, since the period of the cleaning process is reduced, the productivity thereof may be increased.

On the other hand, if the diffusion processes are implemented several times, the polymer is generated in the reaction tube 100 by the condensation of the reactive gas.

At this time, without inserting the wafer 126 in the boat 114, a cleaning gas can be introduced into the reaction tube 100 via the gas injection tube 118. Simultaneously, the in-situ process causing the plasma reaction can be implemented therein, thereby eliminating the polymer formed in the reaction tube 100. For example, NF₃ is utilized as the cleaning gas, and NF₃ is injected, preferably at a flow rate of about 0.5 liter/min, via the gas injection tube 118. In the past, the polymer of a desired thickness is formed on the outer periphery of the tube 100 enclosing the plasma electrode 122 by the condensation of the reactive gas and the electrostatic force generated during the plasma reaction under the heater block, i.e., the reaction tube 100, through the diffusion process. No the polymer is cleaned with the cleaning gas during the in-situ cleaning process, and is exhausted via the gas exhaust tube 120. The polymer is striped from the tube with the RF power applied to the plasma electrode 122, and is dropped on the plate 112. Hence, in addition to the in-situ cleaning process, an additional wet cleaning process for cleaning the plate 112 may be added.

With the diffuser for use in the equipment for manufacturing the semiconductor devices according to an embodiment of the present invention, however, the protection member 128 is provided from the portion of the plasma electrode 122 inserted into the reaction tube 100 to the heater block 124, so as to prevent the polymer from being generated on the tube 100 enclosing the plasma electrode 122 due to the electrostatic force of the reactive gas flowing thereunder. Hence, the polymer generated on the outer wall of the protection member is cleaned by the flow of the cleaning gas.

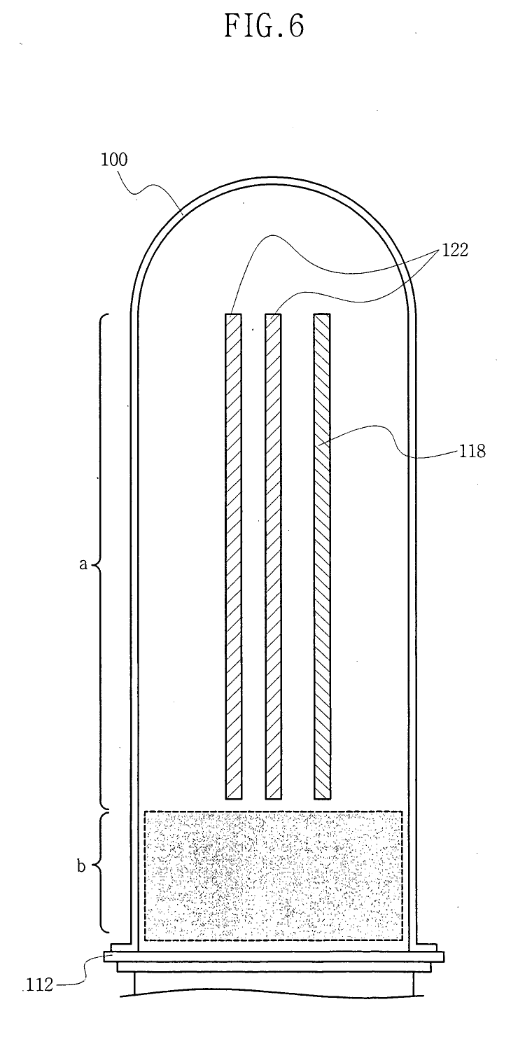

FIG. 6 is a perspective view schematically illustrating the diffuser for use in the equipment for manufacturing semiconductor devices according to an embodiment of the present invention. During the in-situ process, the cleaning gas takes part in the plasma reaction in an upper section a of the reaction tube 100 by the RF power applied from the plasma electrode 122. But the reactive gas does not take part in the plasma reaction in a lower section b of the reaction tube 100 by the protection member 128. Hence, the lower section of the reaction tube 100 may be cleaned by flow of the cleaning gas.

With the diffuser for use in the equipment for manufacturing semiconductor devices according to an embodiment of the present invention, the protection member 128 is installed on the tube 100 enclosing the plasma electrode 122 thereunder. Hence, during the in-situ cleaning process to eliminate the polymer which is generated in the reaction tube 100 during several diffusion processes, the polymer is not stripped in a mass from the protection member 128 by the RF power applied from the plasma electrode 122, and an additional wet cleaning process to clean the polymer is not necessarily, thereby increasing productivity.

In addition, the above embodiment is merely illustrative of the present invention, and is not limited thereto. For example, width, height and thickness of the protection member 128 to protect the tube, which encloses the outer periphery of the plasma electrode 122 under the reactive tube 100 from the reactive gas, may be varied.

With the diffuser for use in the equipment for manufacturing the semiconductor devices according to an embodiment of the present invention, the protection member is provided from a portion of the plasma electrode 122 inserted into the reaction tube 100 to the heater block under the wafers inserted into the boat. This is to prevent the polymer from being generated on the tube 100 enclosing the plasma electrode 122 due to the electrostatic force of the reactive gas flowing under the reaction tube 100. Hence, since the period of the cleaning process is reduced, the productivity thereof may be increased.

With the diffuser for use in the equipment for manufacturing semiconductor devices according to an embodiment of the present invention, the protection member is installed on the tube 100 enclosing the plasma electrode 122 thereunder. Hence, during the in-situ cleaning process to eliminate the polymer which is generated in the reaction tube 100 during several diffusion processes, the polymer is not stripped in a mass from the protection member by the RF power applied from the plasma electrode 122 In addition, a wet cleaning process to clean the polymer is not necessarily performed, thereby increasing productivity.

The invention has been described using preferred exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed is:

1. A diffuser for use in equipment for manufacturing semiconductor devices, the diffuser comprising:
a reaction pipe;
a plate located under the reaction pipe for sealing the reaction pipe and defining a work space therewithin, the work space arranged and structured to contain a plurality of wafers therein;
a gas injection tube for supplying a reactive gas to the work space;
a plurality of plasma electrodes adjacent to the gas injection tube for applying high frequency power to a reactive gas to induce a plasma reaction; and
a protection member adapted to cover a portion of the plasma electrodes inserted into the reaction tube located under the plurality of wafers, for preventing a substantial amount of polymer from being formed under the reactive tube due to a plasma reaction in the reactive gas.

2. The diffuser according to claim 1, wherein the gas injection tube injects phosphorous.

3. The diffuser according to claim 1, wherein the plasma electrode applies about 50 to 800 W RF power to induce the plasma reaction in the reactive gas.

4. The diffuser according to claim 1, wherein the protection member has an area more than an interval between the plurality of plasma electrodes.

5. The diffuser according to claim 1, wherein the protection member encloses the plurality of plasma electrodes.

6. The diffuser according to claim 1, wherein the protection member is made of 30 quartz.

7. The diffuser according to claim 1, wherein the protection member is adapted to form a vacuum therein or be filled with inert gas therein.

8. The diffuser according to claim 7, wherein the inert gas is nitrogen or argon.

9. The diffuser according to claim 7, wherein when the protection member is filled with the inert gas, and/or the protection member is sealed and/or the protection member is filled with the inert gas which is circulated at a predetermined pressure.

10. The diffuser according to claim 1, wherein NF₃ cleaning gas is injected via the gas injection tube.

11. A diffuser for use in an equipment for manufacturing semiconductor devices, the diffuser comprising:
a reaction pipe;
a plate located under the reaction pipe for sealing the reaction pipe and defining a work space therewithin;
a boat located in work space for inserting a plurality of wafers and a plurality of heater blocks into the reaction pipe;
a heater for increasing temperature in the work space;
a gas injection pipe located within the reaction for injecting reactive gas onto the wafers;
a gas exhaust pipe for exhausting the reactive gas injected onto the wafer;
a plurality of plasma electrodes located adjacent to the gas injection tube for applying high frequency power to the reactive gas supplied from the gas injection tube to induce a plasma reaction; and
a protection member for preventing a substantial amount of polymer from being formed on the plate.

12. The diffuser according to claim 11, wherein the gas injection tube injects phosphorous.

13. The diffuser according to claim 11, wherein the plasma electrode applies about 50 to 800 W RF power to induce the plasma reaction in the reactive gas.

14. The diffuser according to claim 11, wherein the protection member has an area more than an interval between the plurality of plasma electrodes.

15. The diffuser according to claim 11, wherein the protection member has a encloses the plurality of plasma electrodes.

16. The diffuser according to claim 11, wherein the protection member is made of quartz.

17. The diffuser according to claim 11, wherein the protection member is adapted to be vacuumed therein or be filled with inert gas therein.

18. The diffuser according to claim 17, wherein the inert gas is nitrogen or argon.

19. The diffuser according to claim 17, wherein when the protection member is filled with the inert gas, the protection member is sealed or the inert gas is circulated at a predetermined pressure.

20. The diffuser according to claim 11, wherein NF₃ cleaning gas is injected at via the gas injection tube.
